(19) United States
(12) Patent Application Publication
(10) Pub. No.: US 2018/0234050 A1
(43) Pub. Date: Aug. 16, 2018

(54) POWER PANEL ASSEMBLY INCLUDING SOLAR PANEL AND SOLAR THERMAL HEAT EXCHANGER, AND METHOD FOR MAKING THE POWER PANEL ASSEMBLY

(71) Applicant: RG Resource Technologies, Inc., Oxford, MI (US)

(72) Inventor: Garth James Schultz, Oxford, MI (US)

(21) Appl. No.: 15/888,297

(22) Filed: Feb. 5, 2018

Related U.S. Application Data
(63) Continuation-in-part of application No. 13/149,153, filed on May 31, 2011.
Application No. 13/149,153 is a continuation-in-part of application No. 12/681,749, filed on Apr. 5, 2010, now Pat. No. 8,476,522.
(60) Provisional application No. 60/977,407, filed on Oct. 4, 2007.

(51) Int. Cl. H02S 40/44; H01L 31/048; H01L 31/18

(52) U.S. Cl. CPC H02S 40/44; H01L 31/0481; B29C 69/02; F24J 2/0023; H01L 31/1876

(57) ABSTRACT

A power panel assembly according to the present disclosure includes a photovoltaic (PV) panel and an enclosure. The PV panel includes a plurality of PV cells and a PV cell tray having a top surface on which the plurality of PV cells are placed and a bottom surface opposite of the top surface. The enclosure includes an inner plate supporting the PV panel and an outer shell having a plurality of sidewalls surrounding the inner plate. The inner plate and the PV panel define a fluid flow path therebetween that allows fluid to flow between the PV panel and the enclosure and absorb heat from the PV panel. The inner plate and the outer shell define a channel therebetween that extends around an outer perimeter of the inner plate and separates the inner plate and the outer shell from one another.

### FIELD

The present disclosure relates to power panel assemblies that include a solar panel and a solar thermal heat exchanger, and to methods for making such power panel assemblies.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Some power panel assemblies include both a solar panel that uses solar energy to generate electricity, and a solar thermal heat exchanger that uses solar energy to heat a fluid (e.g., water) passing therethrough. A solar panel typically includes a plurality of photovoltaic (PV) cells, a PV cell tray that holds the PV cells, and wiring that transmits electricity generated by the cells to a connector. A solar thermal heat exchanger typically includes an enclosure that supports and surrounds the solar panel, a transparent (e.g., glass) panel that encloses the solar panel within the interior of the enclosure while exposing the solar panel to sunlight, and a fluid flow channel that allows fluid to absorb heat from the solar panel.

In some power panel assemblies, the fluid flow channel is disposed between the top surface of the enclosure and the bottom surface of the solar panel (i.e., the surface of the solar panel that rests on the top surface of the enclosure). The transparent panel traps heat within the interior of the enclosure, and the PV cell tray transfers this heat to fluid flowing through the fluid flow channel. In addition, the PV cell tray electrically isolates the PV cells from the remainder of the power panel assembly. Thus, it is desirable for the PV cell tray to have good thermal conductivity and high dielectric strength.

In some cases, heat may be transferred from the PV cell tray to the enclosure and may escape the solar thermal heat exchanger through the back side of the enclosure (i.e., the side of the enclosure opposite of the side that supports the solar panel). If this occurs, the heat is not transferred to fluid flowing through the fluid flow channel, which reduces the efficiency of the solar thermal heat exchanger. Thus, it is desirable for the enclosure act as a thermal insulator that prevents heat from escaping through the back side thereof.

### SUMMARY

A power panel assembly according to the present disclosure includes a photovoltaic (PV) panel and an enclosure. The PV panel includes a plurality of PV cells and a PV cell tray having a top surface on which the plurality of PV cells are placed and a bottom surface opposite of the top surface. The enclosure includes an inner plate supporting the PV panel and an outer shell having a plurality of sidewalls surrounding the inner plate. The inner plate and the PV panel define a fluid flow path therebetween that allows fluid to flow between the PV panel and the enclosure and absorb heat from the PV panel. The inner plate and the outer shell define a channel therebetween that extends around an outer perimeter of the inner plate and separates the inner plate and the outer shell from one another.

In one example, the enclosure further includes a bottom plate disposed below the inner plate, and the plurality of sidewalls project from a top surface of the bottom plate.

In one example, the power panel assembly further includes a transparent panel disposed above the PV panel and supported by a ledge extending around an inner perimeter of the outer shell of the enclosure. In this example, the transparent panel, the PV panel, and the outer shell form an enclosed space therebetween for holding air that is heated by solar energy and transmits heat to the PV panel.

In one example, the inner plate of the enclosure includes a plurality of wall segments projecting from a top surface of the inner plate and at least partially forming sidewalls of the fluid flow path.

In one example, the power panel assembly further includes an adhesive sealant providing a seal between the bottom surface of the PV cell tray and the plurality of wall segments. In this example, the plurality of wall segments and the adhesive sealant collectively form the sidewalls of the fluid flow path.

In one example, the PV panel includes a plurality of wall segments projecting from the bottom surface of the PV cell tray and disposed between adjacent ones of the plurality of wall segments on the inner plate for improving heat transfer from the PV panel to fluid flowing through the fluid flow path.

In one example, a ratio of an area of the top surface of the PV cell tray to an area within an outer perimeter of the outer shell of the enclosure is greater than or equal to 85 percent.

In one example, the enclosure includes a glass-filled thermoplastic material.

In one example, a percentage of glass included in the glass-filled thermoplastic material is within a range from 15 to 30 percent by volume.

In one example, the enclosure further includes foam that fills and insulates a space between the inner plate and the outer shell and has an R value that is greater than or equal to 4.5 per inch.

In one example, the PV cell tray is plastic.

In one example, the PV cell tray has a coefficient of linear thermal expansion within a range from 0.000036 mm/mm per degree Kelvin to 0.000050 mm/mm per degree Kelvin.

In one example, the PV cell tray has a thickness within a range from 1 millimeter (mm) to 2 mm.

Another power panel assembly according to the present disclosure includes a photovoltaic (PV) panel and an enclosure. The PV panel includes a plurality of PV cells and a plastic PV cell tray having a top surface on which the plurality of PV cells are placed and a bottom surface opposite of the top surface. The enclosure includes an inner plate supporting the PV panel and an outer shell having a plurality of sidewalls surrounding the inner plate. The inner plate of the enclosure and the PV panel define a fluid flow path therebetween that allows fluid to flow between the PV panel and the enclosure and absorb heat from the PV panel.

In one example, the plastic PV cell tray has a coefficient of linear thermal expansion within a range from 0.000036 mm/mm per degree Kelvin to 0.000050 mm/mm per degree Kelvin.

In one example, the inner plate of the enclosure includes a plurality of wall segments projecting from a top surface of the inner plate and at least partially forming sidewalls of the fluid flow path, and the PV panel includes a plurality of wall segments projecting from the bottom surface of the plastic PV cell tray and disposed between adjacent ones of the plurality of wall segments on the inner plate for improving heat transfer from the PV panel to fluid flowing through the fluid flow path.

In one example, the inner plate and the outer shell define a channel therebetween that extends around an outer perimeter of the inner plate and separates the inner plate and the outer shell from one another.

An example method of making a power panel assembly according to the present disclosure includes blow molding an enclosure from a glass-filled thermoplastic material, the enclosure including an inner plate and an outer shell surrounding the inner plate, filling the enclosure with an insulating foam, separating the inner plate from the outer shell, placing a plurality of photovoltaic (PV) cells on a (PV) cell tray to form a PV panel, and placing the PV panel on the inner plate.

In one example, the method further includes separating the inner plate from the outer shell by cutting the enclosure along an outer perimeter of the inner plate.

In one example, the method further includes injection molding the PV cell tray from a thermally conductive plastic material.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a perspective view of a power panel assembly according to the principles of the present disclosure;

FIG. 2 is an exploded perspective view of the power panel assembly of FIG. 1 illustrating an enclosure, a photovoltaic (PV) cell tray, PV cells, wiring, and a transparent panel included in the power panel assembly;

FIG. 3 is a perspective view of the enclosure of FIG. 2;

FIG. 4 is a cross-sectional perspective view of a portion of the enclosure of FIG. 2 taken along a line 4-4 shown in FIG. 3;

FIG. 5 is a bottom perspective view of the enclosure of FIG. 2;

FIG. 6 is a top view of the enclosure of FIG. 2;

FIG. 7 is an enlarged top view of a portion of the enclosure of FIG. 2 within an area 7 shown in FIG. 6;

FIG. 8 is a top view of the power panel assembly of FIG. 1;

FIG. 9 is a cross-sectional view of the power panel assembly of FIG. 1 taken along a line 9-9 shown in FIG. 8;

FIG. 10 is an enlarged cross-sectional view of the power panel assembly of FIG. 1 within an area 10 shown in FIG. 9;

FIG. 11 is a bottom perspective view of the PV cell tray of FIG. 2;

FIG. 12 is a top perspective view of the PV cell tray of FIG. 2;

FIG. 13 is a perspective view of the PV cell tray of FIG. 2 assembled to the enclosure of FIG. 2, with the PV cell tray shown in phantom to illustrate the interface between the PV cell tray and the enclosure; and

FIG. 14 is a flowchart illustrating a method of making a power panel assembly according to the principles of the present disclosure.

In the drawings, reference numbers may be reused to identify similar and/or identical elements.

### DETAILED DESCRIPTION

In existing power panel assemblies, the enclosure typically includes an outer shell that is vacuum formed from a plastic and filled with an insulating foam. The outer shell typically covers the top surface of the enclosure that supports the PV cell tray and the side surfaces of the enclosure that surround the PV cell tray, but does not cover the back or bottom surface of the enclosure opposite the top surface of the enclosure. Therefore, the insulating foam must be rigid enough to form the bottom surface of the enclosure. The insulating R value of foams that are able to perform this function is typically limited. For example, one such foam is expanded polypropylene, which has an R value of approximately 4.2 per inch of thickness.

Ideally, the insulating foam in existing power panel assemblies bonds to the outer shell to maintain the structural integrity of the outer shell. However, if the outer shell were allowed to cool after being vacuum formed, the outer shell would likely pull away from the insulating foam. Thus, the outer shell is typically vacuum formed and filled with the insulating foam using a single machine that is capable of preforming both operations during a short period so that the outer shell is not allowed to cool before the fill operation. The cost of a machine with this capability is high, which increases the cost of existing power panel assemblies.

Since the outer shell of existing power panel assemblies are typically vacuum formed, the materials from which the outer shell can be made are limited to those that can withstand the vacuum forming process such as thermoplastic polyolefin (TPO). However, materials that can be vacuum formed typically have a lower performance rating when subjected to high temperatures for sustained periods (e.g., their maximum operating temperature is lower). In addition, materials that can be vacuum formed typically have a much higher coefficient of linear thermal expansion (CLTE) than the transparent panel. Since the transparent panel is typically bonded to the outer shell, the outer shell has a tendency to bend or bow outward when the outer shell expands by a greater amount than the transparent panel, which may cause damage to the enclosure.

In contrast, a power panel assembly according to the present disclosure includes an enclosure having an outer shell that is blow molded. Blow molding the enclosure enables reducing the total area of the power panel assembly by using small draft angles, which increases the ratio of energy generating area (i.e., the area of the solar panel) to the total area and thereby improves the efficiency of the power panel assembly. Also, since the outer shell is blow molded rather than vacuum formed, the outer shell may be formed from a glass-filled thermoplastic material that enables the outer shell to withstand higher temperatures for sustained periods. In addition, the glass-filled thermoplastic material has a lower CLTE than the outer shells of existing power panel assemblies, which inhibits or prevents damage to the outer shell caused by part growth. Further, the outer shell covers the back side of the enclosure, which enables filling the outer shell with an insulating foam with a higher R value. In one example, the insulating foam is a polyurethane foam with an R value of 6.6 per inch.

Moreover, since the outer shell is blow molded rather than vacuum formed, the outer shell may be allowed to cool before filling the outer shell with the insulating foam. In turn, the vacuum form and foam filling operations may be performed using two different, low cost machines. This significantly reduces the cost of making the power panel assembly relative to the cost of making existing power panel assemblies.

While the term “outer shell” has thus far been used to refer to the entire outer surface of the enclosure, in the description that follows, the outer shell refers only to the sidewalls of the enclosure and the back or bottom surface of the enclosure. The top surface of the enclosure that supports the PV cell tray is referred to as an inner plate. In one example, a relief channel is formed in the enclosure between the inner plate and the outer enclosure, which reduces stress on an adhesive attaching the PV cell tray to the inner plate. As a result, the adhesive between the inner plate and the PV cell tray is less likely to be damaged due to differences between the rates at which the enclosure and the transparent panel shrink and expand as the temperature changes.

The PV cell tray in existing power panel assemblies is typically formed from a metal having good thermal conductivity, such as aluminum, and then an anodized coating is applied to the outer surface of the PV cell tray to electrically insulate the PV cells. The metal forming and anodized coating operations may be performed at two different locations, which introduces risk that the PV cell tray may be damaged during shipment between the two locations. In addition, the anodized coating is relatively thin (e.g., 0.002 inches thick). Thus, if the anodized coating becomes scratched, the electrically insulating performance of the PV cell tray is diminished.

In contrast, a PV cell tray of a power panel assembly according to the present disclosure is injection molded from a thermally conductive plastic. Since plastic has a relatively high dielectric strength, there is no need to apply an anodized coating to the outer surface of the PV cell tray, which reduces the likelihood that the PV cell tray will be damaged during manufacturing. Also, the thickness of the PV cell tray is much greater than the thickness of the anodized coating. In one example, the PV cell tray is 0.060 inches (1.5 millimeters) thick. Thus, the PV cell tray is more durable and robust for transport.

In addition, the PV cell tray of an existing power panel assembly has a much lower CLTE than that of an enclosure made of a glass-filled thermoplastic material. In one example, a PV cell tray made of aluminum has a CLTE within a range from 0.000021 mm/mm per degree Kelvin to 0.000023 mm/mm per degree Kelvin, and an enclosure made of a glass-filled thermoplastic has a CLTE within a range from 0.000036 mm/mm per degree Kelvin to 0.000050 mm/mm per degree Kelvin. Thus, attaching the PV cell tray of an existing power panel assembly to an enclosure made of a glass-filled thermoplastic yields high stress on the adhesive holding the enclosure and the PV cell tray together. In contrast, the plastic PV cell tray may have a CLTE that matches that of the enclosure (e.g., within a range from 0.000036 mm/mm per degree Kelvin to 0.000050 mm/mm per degree Kelvin). Thus, the PV cell tray may shrink and expand due to changes in temperature at approximately the same rate as the enclosure, which reduces stress on the adhesive holding the enclosure and the PV cell tray together.

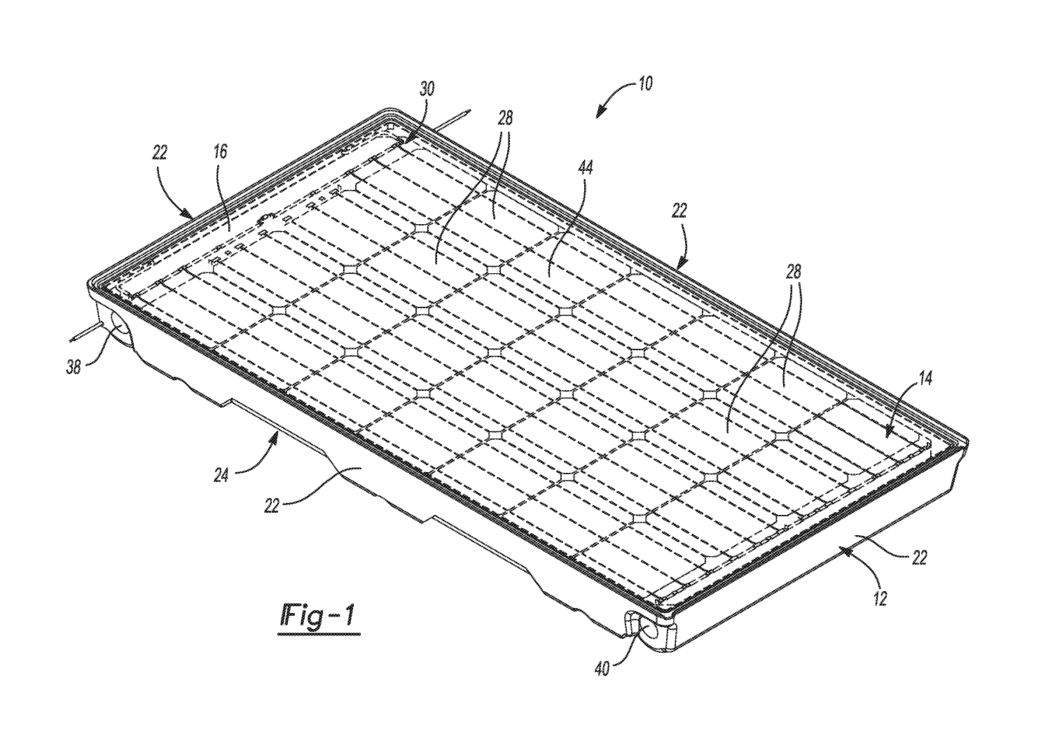

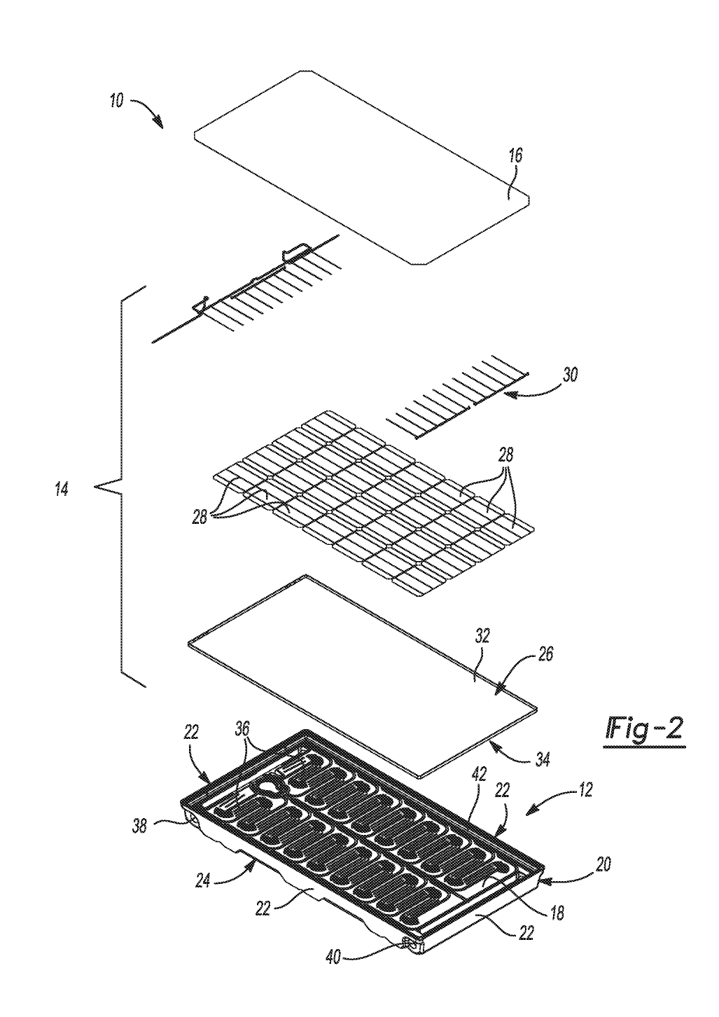

Referring now to FIGS. 1 and 2, a power panel assembly 10 includes an enclosure 12, a photovoltaic (PV) panel 14, and a transparent panel 16. The enclosure 12 includes an inner plate 18 that supports the PV panel 14 and an outer shell 20 having a plurality of sidewalls 22 that surround the inner plate 18 and a bottom plate 24 disposed below the inner plate 18. The sidewalls 22 of the outer shell 20 project from the bottom plate 24 of the outer shell 20.

The enclosure 12 may be blow molded from a glass-filled thermoplastic material (e.g., glass-filled polypropylene, glass-filled nylon) that is able to withstand high temperatures while having a relatively low CLTE. The percentage of glass included in the glass-filled thermoplastic material may be within a range from 15 to 30 percent by volume. The glass-filled thermoplastic material may have a CLTE within a range from 0.000036 mm/mm per degree Kelvin to 0.000050 mm/mm per degree Kelvin.

The PV panel 14 includes a PV cell tray 26, a plurality of PV cells 28 that are supported by the PV cell tray 26 and that convert solar energy into electrical energy, and wiring 30 that transmits electrical energy generated by the PV cells 28. The PV cell tray 26 has a top surface 32 that supports the PV cells 28 and a bottom surface 34 opposite of the top surface 32. The bottom surface 34 of the PV cell tray 26 and the inner plate 18 define a plurality of fluid flow paths 36 therebetween. The fluid flow paths 36 allow fluid (e.g. water) to flow between the PV panel 14 and the inner plate 18 and absorb heat from the PV panel 14.

The PV cell tray 26 may be injection molded from a thermally conductive plastic material, such as Celanese CoolPoly® E3607 Thermally Conductive Polyamide (PA6), that provides sufficient thermal conductivity and dielectric strength. Increasing the thermal conductivity of the PV cell tray 26 improves the ability of the PV cell tray 26 to transfer heat to fluid flowing through the fluid flow paths 36. However, plastic materials with a higher thermal conductivity typically have a lower dielectric strength, and the dielectric strength of the PV cell tray 36 should be sufficient to electrically insulate the PV cells 28 from the enclosure 12 and the fluid flowing through the fluid flow paths 36. Thus, the PV cell tray 26 may be injection molded from a thermally conductive plastic material, such as that identified above, which strikes a balance between thermal conductivity and dielectric strength. In one example, the thermal conductivity of the PV cell tray 26 may be within a range from 10 Watt per meter-Kelvin (W/m-K) to 15 W/m-k (e.g., 14 W/m-K). In another example, the dielectric strength of the PV cell tray 26 may be within a range from 100 kilovolts per centimeter (kV/cm) to 300 kV/cm (e.g., 200 kV/cm).

The PV cell tray 26 may have a thickness within a range from 1 mm to 2 mm. Thus, the PV cell tray 26 may be a more durable electrical insulator relative to existing PV cell trays that are made of metal and have a relatively thin (e.g., 0.002 inch thick) anodized coating. For example, while the dielectric properties of such an existing PV cell tray may breakdown if the anodized coating is scratched, the dielectric strength of the PV cell tray 26 is unlikely to be affected by surface scratches.

The enclosure 12 has an inlet 38 and an outlet 40 disposed opposite ends thereof and extending through the sidewalls 22 of the outer shell 20. Fluid enters the power panel assembly 10 through the inlet 38 and flows to the fluid flow paths 36. After passing through the fluid flow paths 36, fluid exits the power panel assembly 10 through the outlet 40. The temperature of fluid exiting the power panel assembly 10 through the outlet 40 is typically greater than the temperature of fluid entering the power panel assembly 10 through the inlet 38 since fluid absorbs heat from the PV panel 14 as it flows through the fluid flow paths 36.

The transparent panel 16 is supported by a ledge 42 extending around the inner perimeter of the outer shell 20 of the enclosure 12 and disposed above the PV panel 14. The transparent panel 16, the PV panel 14, and the outer shell 20 of the enclosure 12 form an enclosed space 44 (FIG. 10) therebetween for holding air that is heated by solar energy and that transmits heat to the PV panel 14. The transparent panel 16 forms the cover or ceiling of this enclosed space while allowing sunlight to pass therethrough. The transparent panel 16 may be formed from a clear plastic or glass.

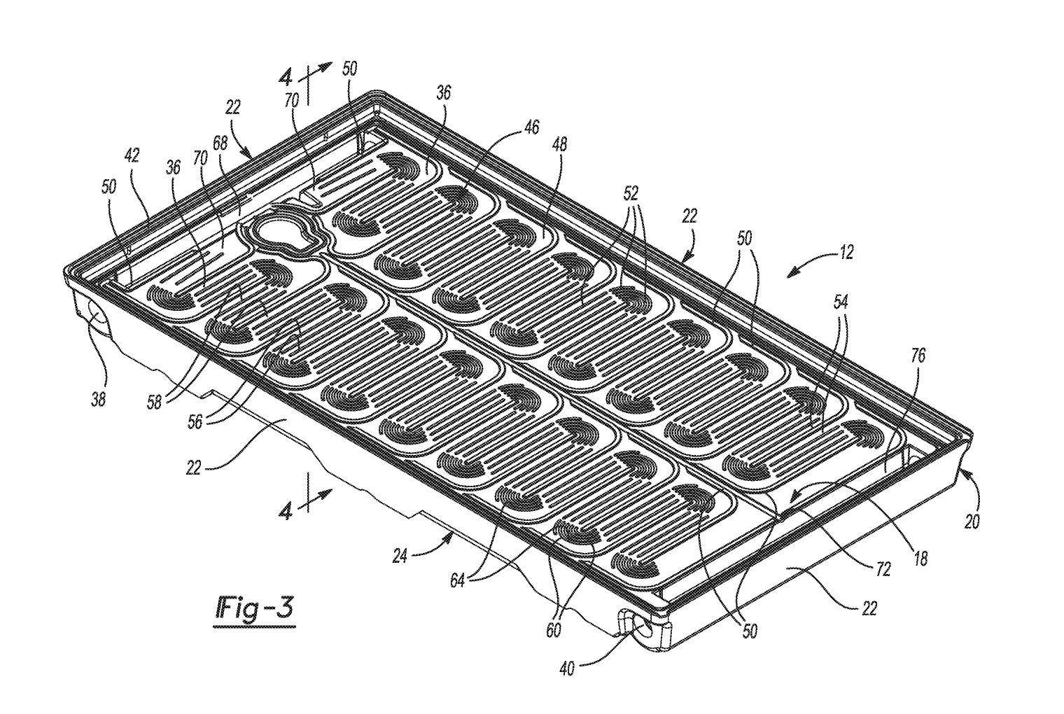

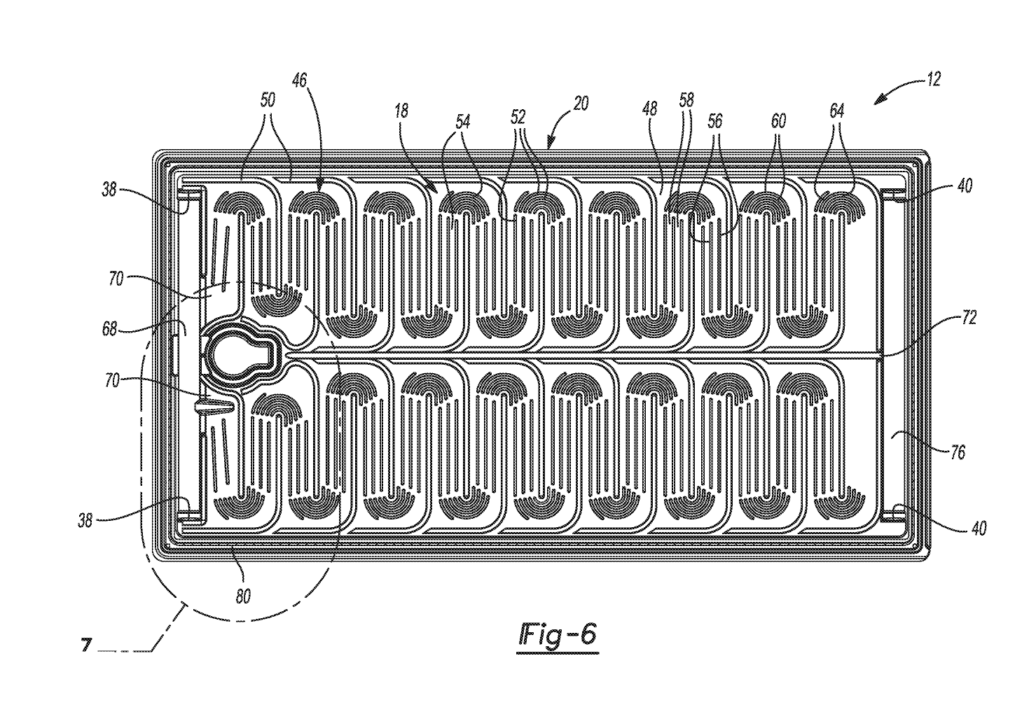

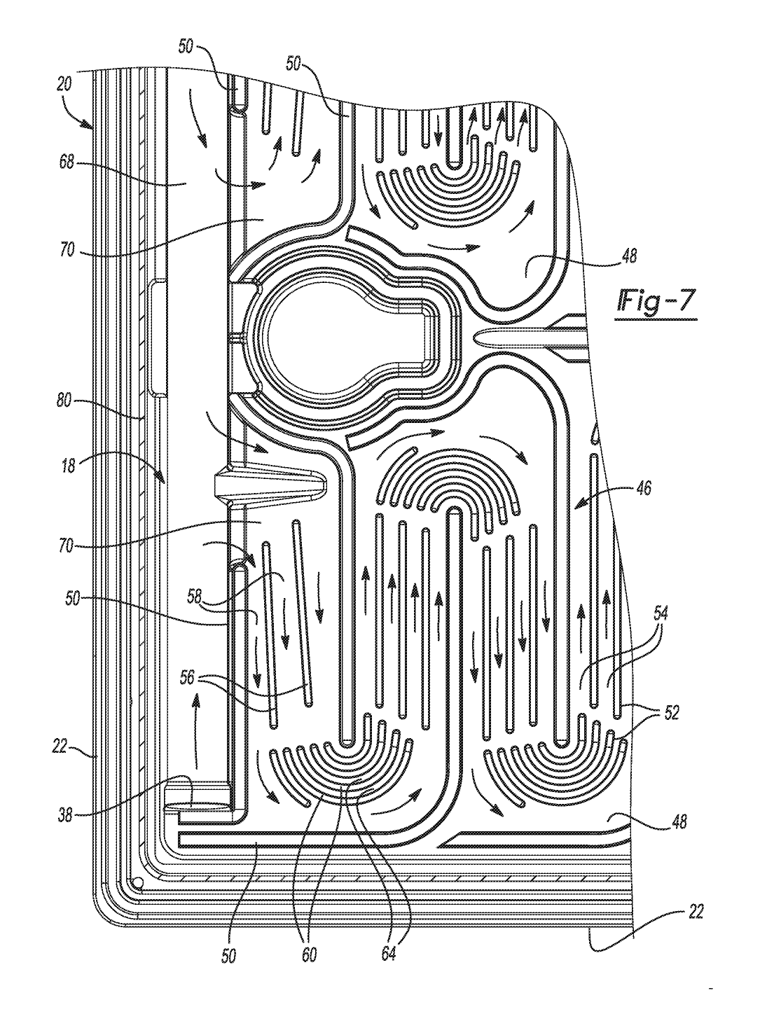

Referring now to FIGS. 3-7, the inner plate 18 of the enclosure 12 includes a plurality of wall segments 46 projecting from a top surface 48 of the inner plate 18. The wall segments 46 include outer wall segments 50 that define the outer boundaries of the fluid flow paths 36 and inner wall segments 52 that define fluid flow channels 54 within the fluid flow paths 36. The inner wall segments 52 include straight segments 56 that define straight portions 58 of the fluid flow channels 54 and curved segments 60 that define curved portions 64 of the fluid flow channels 54.

Fluid flows from the inlet 38 of the enclosure 12 to an inlet manifold 68 (e.g., a U-shaped channel), and then enters the fluid flow paths 36 through path entrances 70 defined by the outer wall segments 50. Fluid flows from the path entrances 70 to a path exit 72 that is also defined by the outer wall segments 50. As fluid passes through the fluid flow paths 36 from the path entrances 70 to the path exit 72, fluid may flow between different ones of the fluid flow channels 54. After passing through the path exit 72, fluid enters an outlet manifold 76 (e.g., a U-shaped channel) and then exits the outlet manifold 76 through the outlet 40 of the enclosure 12.

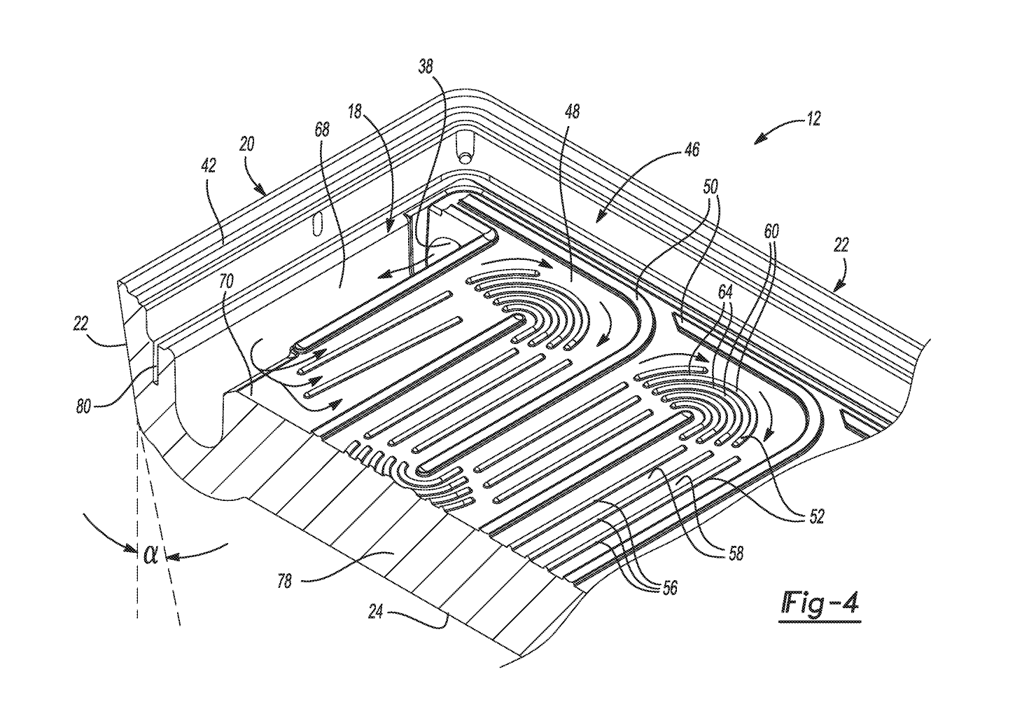

With particular reference to FIG. 4, the interior space of the enclosure 12 (i.e., the space between the inner plate 18 and the outer shell 20) is filled with an insulating foam 78 that insulates the interior space of the enclosure 12. The insulating foam 78 may adhere to the inner plate 18 and the outer shell 20 and therefore hold the inner plate 18 in position relative to the outer shell 20. The insulating foam 78 may be a polyurethane foam and/or may have an R value that is greater than or equal to 4.5 per inch (e.g, from 5 per inch to 8 per inch, from 5.5 per inch to 7.5 per inch, from 6 per inch to 7 per inch, from 6.5 per inch to 6.7 per inch, and/or equal to 6.6 per inch). Due to the R value of the insulating foam 78, there is less heat loss through the back side (or the bottom plate 24) of the enclosure 12, which improves the efficiency of the power panel assembly 10, especially when operating at a higher differential temperature (i.e., a higher difference between ambient temperature and the temperature of fluid at the inlet 38 of the power panel assembly 10).

After the enclosure 12 is filled with the insulating foam 78, a relief channel 80 is machined (e.g., cut) into the enclosure to separate the inner plate 18 and the outer shell 20 from one another. After the relief channel 80 is formed, the inner plate 18 and the outer shell 20 may be held together by the insulating foam 78 alone. The transparent panel 12 is placed on the ledge 42 of the enclosure 12 and is secured thereto using, for example, adhesive. As the temperature of air in the space 44 between the transparent panel 16 and the enclosure 12 changes, the transparent panel 16 may shrink and expand at a different rate than the enclosure 12. The relief channel 80 allows the outer walls 22 of the enclosure 12 to move relative to the inner plate 18 of the enclosure 12, which reduces stress on an attachment between the inner plate 18 and the PV panel 14. As a result, the attachment between the inner plate 18 and the PV panel 14 is less likely to be damaged due to differences between the rates at which the enclosure 12 and the transparent panel 16 shrink and expand.

The sidewalls 22 of the enclosure 12 have a draft angle α with respect to vertical that has a negative value as a result of blow molding the enclosure 12. The draft angle α is the angle that the sidewalls 22 extend outward (i.e., in a direction away from the inner plate 18) with respect to vertical in a direction 81. Since the sidewalls 22 extend inward (i.e., in a direction toward the inner plate 18) with respect to vertical in the direction 81, the draft angle α of the sidewalls 22 is negative.

Since the draft angle α of the sidewalls 22 is negative, the gross area of the enclosure 12 (i.e., the maximum area of the enclosure 12 between the outer perimeter thereof) may be less than that of existing enclosures. To this end, existing enclosures typically have a positive draft angle, and therefore the maximum area of an existing enclosure is typically the area of the bottommost portion of the existing enclosure within the outer perimeter thereof. In contrast, since the draft angle α of the sidewalls 22 is negative, the area of the enclosure 12 at the bottom plate 24 is less than the area of the enclosure 12 at the topmost portion of the enclosure 12 (e.g., near the ledge 42). As a result, the gross area of the enclosure 12 is less than that of existing enclosures. In one example, the gross area of an existing enclosure is 0.98 square meters (m²), and the gross area of the enclosure 12 is 0.88 m². Thus, the negative draft angle α of the sidewalls 22 enables a 10 percent reduction in the gross area of the enclosure 12. Decreasing the gross area of the enclosure 12 increases the ratio of energy generating area (i.e., the area within the outer perimeter of the PV panel 26) to the gross area of the enclosure 12 and thereby improves the efficiency of the power panel assembly 10. In one example, the area within the outer perimeter of the PV panel 26 is 0.78 mm² and the gross area of the enclosure 12 is 0.88 m², and therefore the ratio of the energy generating area to the gross area is 0.88. In another example, a ratio of the energy generating area to the gross area is greater than or equal to 85 percent.

The PV cell tray 26 may be injection molded from a thermally conductive plastic material having a CLTE that matches that of the enclosure 12. In one example, the CLTE of the PV cell tray 26 may be within a range from 0.000036 mm/mm per degree Kelvin to 0.000050 mm/mm per degree Kelvin. Thus, the PV cell tray 26 may shrink and expand due to changes in temperature at approximately the same rate as the enclosure 12, which reduces stress on adhesive holding the PV cell tray 26 and the enclosure 12 together.

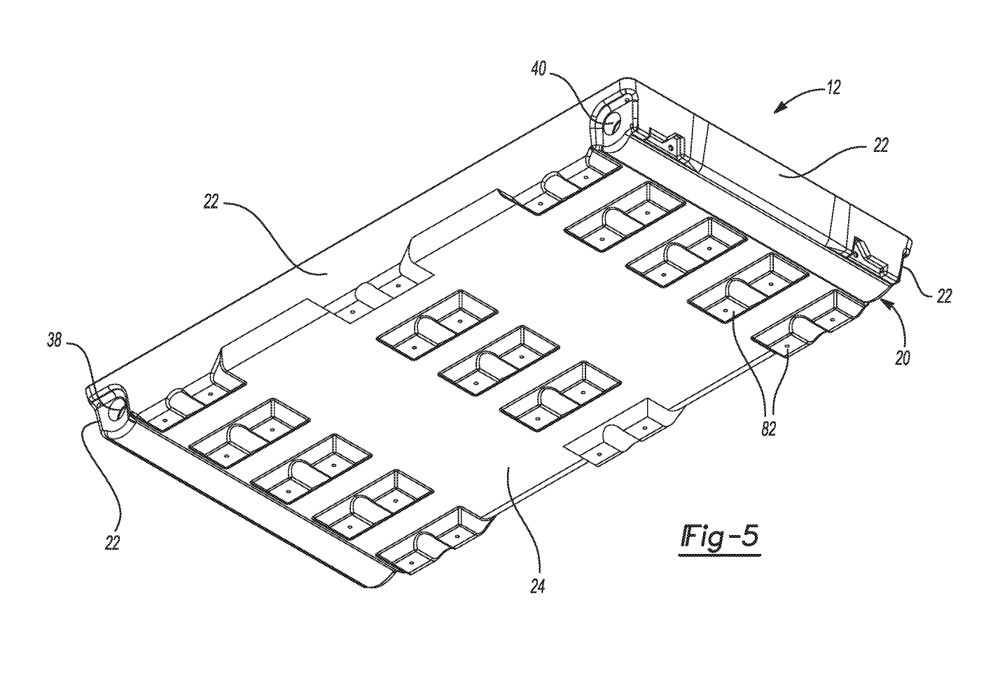

With particular reference to FIG. 5, the enclosure 12 further includes a plurality of mounting feet 82 projecting from the bottom plate 24 of the enclosure 12. The mounting feet 82 may be integrally formed with the remainder of the enclosure 12. Alternatively, the mounting feet 82 may be formed separate from the remainder of the enclosure 12 and attached thereto.

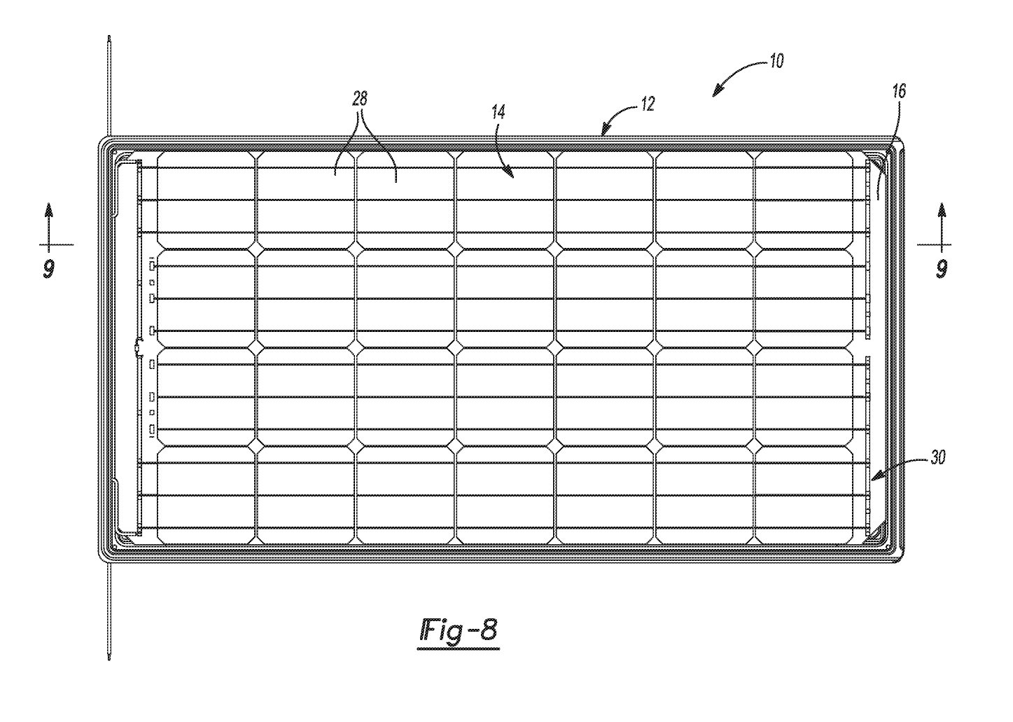

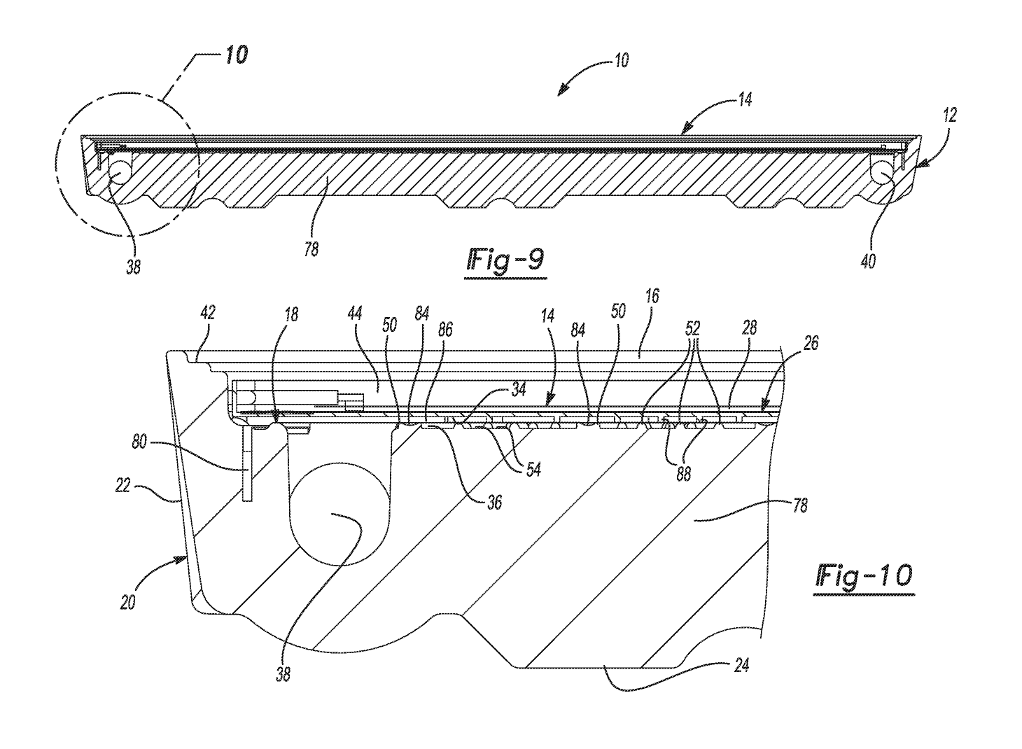

Referring now to FIGS. 8-10, and with particular reference to FIG. 10, the boundaries of the fluid flow paths 36 are formed by the bottom surface 34 of the PV cell tray 26, the top surface 48 of the enclosure 12, and the outer wall segments 50 projecting from the top surface 48. In addition, a groove 84 is formed in the top surface of each outer wall segment 50, and an adhesive sealant 86 is placed in the groove 84 to attach the PV cell tray 26 to the enclosure 12. Thus, the outer wall segments 50 and the adhesive sealant 86 collectively form the side walls of the fluid flow paths 36.

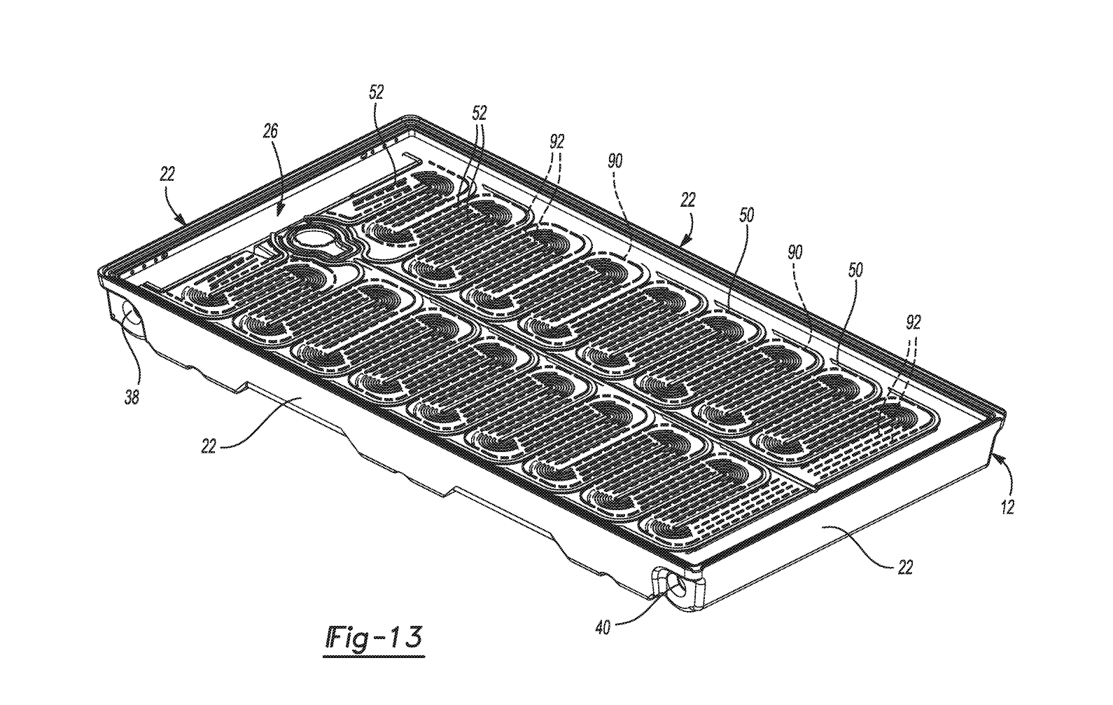

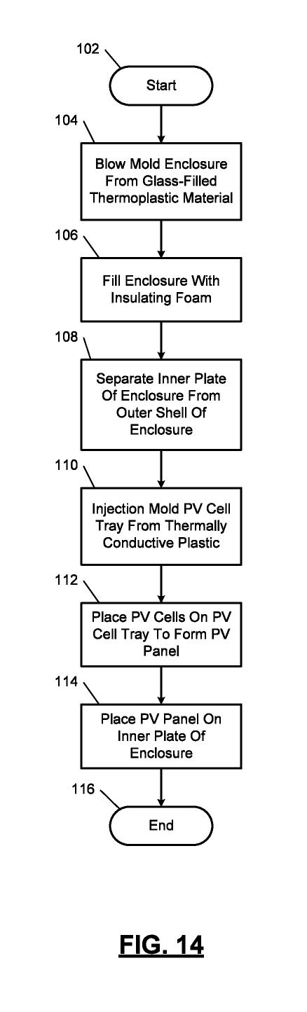

Referring now to FIGS. 10, 11 and 13, the PV cell tray 26 includes a plurality of wall segments 88 projecting from the bottom surface 34 of the PV cell tray 26 and disposed between adjacent ones of the wall segments 46 on the inner plate 18 of the enclosure 12. The wall segments 88 act as cooling fins that dissipate heat from the PV cell tray 26 to fluid flowing through the fluid flow paths 36 and thereby improve heat transfer from the PV panel 26 to fluid flowing through the fluid flow paths 36.

The wall segments 88 of the PV cell tray 26 include outer wall segments 90 and inner wall segments 92. The outer wall segments 90 of the PV cell tray 26 are configured (e.g., shaped, sized) to nest within the outer wall segments 50 of the enclosure 12. The inner wall segments 92 are configured (e.g., shaped, sized) to nest within the inner wall segments 52 of the enclosure 12. The outer wall segments 90 are U-shaped or L-shaped, and the inner wall segments 92 are arranged in straight lines.

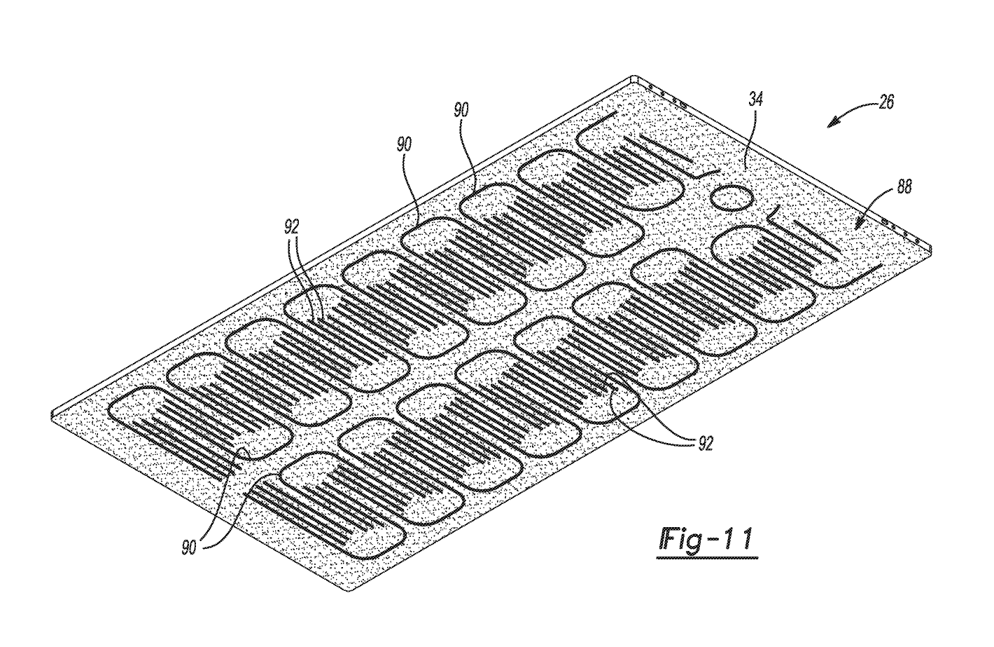

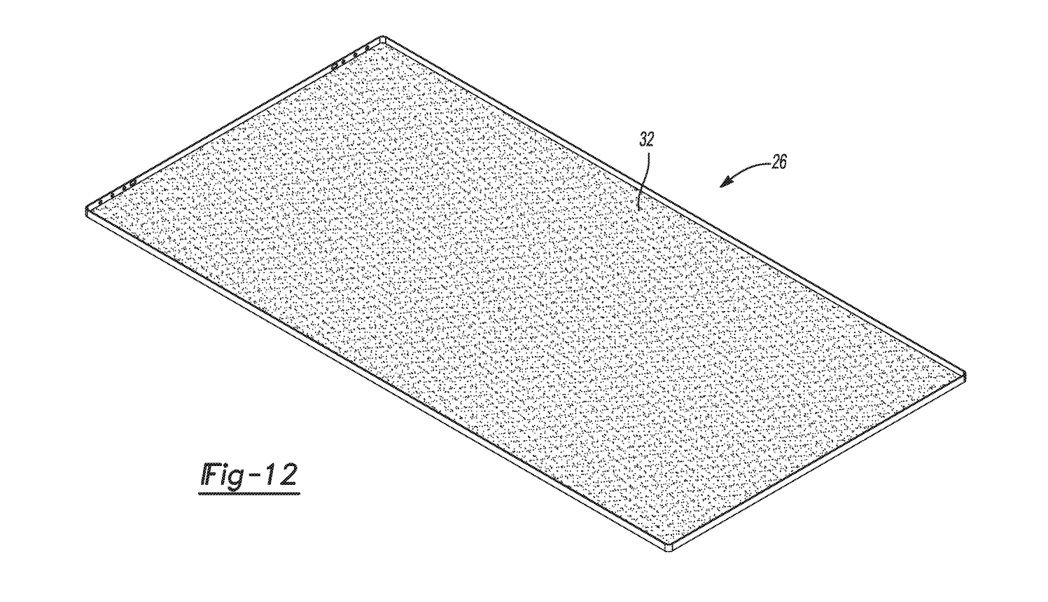

Referring now to FIGS. 11 and 12, the top and bottom surfaces 32 and 34 of the PV cell tray 26 are texturized. For example, the top and bottom surfaces 32 and 34 of the PV cell tray 26 includes a plurality of ridges and valleys, which may be integrally formed from plastic with the remainder of the PV cell tray 26 using injection molding. The texturizing on the top surface 32 of the PV cell tray 26 improves the rate of heat transfer to the PV cell tray 26 from air trapped within the enclosed space 44 between the transparent panel 16, the PV panel 14, and the outer shell 20 of the enclosure 12. The texturizing on the bottom surface 34 of the PV cell tray 26 improves the rate of heat transfer from the PV cell tray 26 to fluid flowing through the fluid flow channels 36.

Referring now to FIG. 14, a method for making a power panel assembly such as the power panel assembly 10 begins at 102. At 104, the method includes blow molding the enclosure 12 from a glass-filled thermoplastic material such as those discussed above. At 106, the method includes filling the interior space of the enclosure 12 with the insulating foam 78.

At 108, the method includes separating the inner plate 18 of the enclosure 12 from the outer shell 20 of the enclosure 12. In one example, the inner plate 18 is separated from the outer shell 20 by using a Computer Numerical Control (CNC) router with a milling bit to form the relief channel 80 in the enclosure 12. At 110, the method includes injection molding the PV cell tray 26 from a thermally conductive plastic material such as those discussed above.

At 112, the method includes placing the PV cells 28 on the top surface 32 of the PV cell tray 26 to form the PV panel 14. The method may also include applying adhesive to the PV cells 28 and/or the PV cell tray 26 before placing the PV cells 28 on the top surface 32 of the PV cell tray 26 in order to attach the PV cells 28 to the PV cell tray 26. The method may further include attaching the wiring 30 to the PV cells 28 before and/or after placing the PV cells 28 on the top surface 32 of the PV cell tray 26.

At 114, the method includes placing the PV panel 14 on the inner plate 18 of the enclosure 12. The method may include applying adhesive to the top surface 84 of the wall segments 46 and/or the bottom surface 32 of the PV panel 14 before placing the PV panel 14 on the inner plate 18 in order to attach the PV panel 14 to the inner plate 18. At 116, the method ends.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

None of the elements recited in the claims are intended to be a means-plus-function element within the meaning of 35 U.S.C. § 112(f) unless an element is expressly recited using the phrase “means for,” or in the case of a method claim using the phrases “operation for” or “step for.”

What is claimed is:

1. A power panel assembly comprising:
a photovoltaic (PV) panel including a plurality of PV cells and a PV cell tray having a top surface on which the plurality of PV cells are placed and a bottom surface opposite of the top surface; and
an enclosure including an inner plate supporting the PV panel and an outer shell having a plurality of sidewalls surrounding the inner plate, the inner plate and the PV panel defining a fluid flow path therebetween that allows fluid to flow between the PV panel and the enclosure and absorb heat from the PV panel, the inner plate and the outer shell defining a channel therebetween that extends around an outer perimeter of the inner plate and separates the inner plate and the outer shell from one another.

2. The power panel assembly of claim 1 wherein the enclosure further includes a bottom plate disposed below the inner plate, wherein the plurality of sidewalls project from a top surface of the bottom plate.

3. The power panel assembly of claim 1 further comprising a transparent panel disposed above the PV panel and supported by a ledge extending around an inner perimeter of the outer shell of the enclosure, wherein the transparent panel, the PV panel, and the outer shell form an enclosed space therebetween for holding air that is heated by solar energy and transmits heat to the PV panel.

4. The power panel assembly of claim 1 wherein the inner plate of the enclosure includes a plurality of wall segments projecting from a top surface of the inner plate and at least partially forming sidewalls of the fluid flow path.

5. The power panel assembly of claim 4 further comprising an adhesive sealant providing a seal between the bottom surface of the PV cell tray and the plurality of wall segments, wherein the plurality of wall segments and the adhesive sealant collectively form the sidewalls of the fluid flow path.

6. The power panel assembly of claim 4 wherein the PV panel includes a plurality of wall segments projecting from the bottom surface of the PV cell tray and disposed between adjacent ones of the plurality of wall segments on the inner plate for improving heat transfer from the PV panel to fluid flowing through the fluid flow path.

7. The power panel assembly of claim 1 wherein a ratio of an area of the top surface of the PV cell tray to an area within an outer perimeter of the outer shell of the enclosure is greater than or equal to 85 percent.

8. The power panel assembly of claim 1 wherein the enclosure includes a glass-filled thermoplastic material.

9. The power panel assembly of claim 8 wherein a percentage of glass included in the glass-filled thermoplastic material is within a range from 15 to 30 percent by volume.

10. The power panel assembly of claim 1 wherein the enclosure further includes foam that fills and insulates a space between the inner plate and the outer shell and has an R value that is greater than or equal to 4.5 per inch.

11. The power panel assembly of claim 1 wherein the PV cell tray is plastic.

12. The power panel assembly of claim 11 wherein the PV cell tray has a coefficient of linear thermal expansion within a range from 0.000036 per Kelvin to 0.000050 per Kelvin.

13. The power panel assembly of claim 11 wherein the PV cell tray has a thickness within a range from 1 millimeters (mm) to 2 mm.

14. A power panel assembly comprising:
a photovoltaic (PV) panel including a plurality of PV cells and a plastic PV cell tray having a top surface on which the plurality of PV cells are placed and a bottom surface opposite of the top surface; and
an enclosure including an inner plate supporting the PV panel and an outer shell having a plurality of sidewalls surrounding the inner plate, the inner plate of the enclosure and the PV panel defining a fluid flow path therebetween that allows fluid to flow between the PV panel and the enclosure and absorb heat from the PV panel.

15. The power panel assembly of claim 14 wherein the plastic PV cell tray has a coefficient of linear thermal expansion within a range from 0.000036 mm/mm per degree Kelvin to 0.000050 mm/mm per degree Kelvin.

16. The power panel assembly of claim 14 wherein:
the inner plate of the enclosure includes a plurality of wall segments projecting from a top surface of the inner plate and at least partially forming sidewalls of the fluid flow path; and
the PV panel includes a plurality of wall segments projecting from the bottom surface of the plastic PV cell tray and disposed between adjacent ones of the plurality of wall segments on the inner plate for improving heat transfer from the PV panel to fluid flowing through the fluid flow path.

17. The power panel assembly of claim 14 wherein the inner plate and the outer shell defining a channel therebetween that extends around an outer perimeter of the inner plate and separates the inner plate and the outer shell from one another.

18. A method of making a power panel assembly comprising:
blow molding an enclosure from a glass-filled thermoplastic material, the enclosure including an inner plate and an outer shell surrounding the inner plate;
filling the enclosure with an insulating foam;
separating the inner plate from the outer shell;
placing a plurality of photovoltaic (PV) cells on a (PV) cell tray to form a PV panel; and
placing the PV panel on the inner plate.

19. The method of claim 18 further comprising separating the inner plate from the outer shell by cutting the enclosure along an outer perimeter of the inner plate.

20. The method of claim 18 further comprising injection molding the PV cell tray from a thermally conductive plastic material.
